(19) United States
(12) Patent Application Publication
(10) Pub. No.: US 2026/0291258 A1
(43) Pub. Date: Sep. 24, 2026

(54) AUTOMOBILE BATTERY REMOTE CHARGING AND MAINTENANCE SYSTEM

(71) Applicant: Guidepoint Systems, dba GPSi LLC, Madison Heights, MI (US)

(72) Inventor: Robert Cameron Jones, Detroit, MI (US)

(21) Appl. No.: 19/472,339

(22) PCT Filed: Apr. 3, 2024
(86) PCT No.: PCT/US2024/022875

§ 371 Date: Oct. 3, 2025

Related U.S. Application Data
(60) Provisional application No. 63/493,791, filed on Apr. 3, 2023.

(51) Int. Cl. H02J 7/14; G07C 5/00; H04W 4/44

(52) U.S. Cl. CPC H02J 7/1446; G07C 5/008; H04W 4/44

(57) ABSTRACT

A vehicle battery recharging system includes a vehicle having a telematics system and a remote computing device in signal communication with the telematics system via a network. The telematics system includes a controller, a wireless communication transceiver, and a plurality of monitoring devices for determining a state of charge of a battery of the vehicle and a condition of components of vehicle utilized in determining whether a charging session can be safely and securely initiated by the remote computing device. The remote computing device automatically sends a signal starting an internal combustion engine of the vehicle to initiate a charging session of the battery when an algorithm of the remote computing device determines that a set of conditions are met regarding a state of the components of the vehicle and regarding an environment in which the vehicle is located.

### CROSS-REFERENCE TO RELATED APPLICATION

This patent application claims priority to U.S. Provisional Patent Application Ser. No. 63/493,791, filed on Apr. 3, 2023, the entire disclosure of which is hereby incorporated herein by reference.

### BACKGROUND OF THE INVENTION

The internal combustion engine (ICE) is still the prevalent method of propulsion for automobiles around the world, and will remain so for many years. Internal combustion engines are powered by gasoline or diesel fuel, typically, but rely on a battery to start the engine, and help regulate the vehicles electrical system.

Vehicle batteries, typically of lead acid chemistry, are prone to wear-out, and have relatively short lifespans of 3-5 years. Battery life can be significantly shortened to days or weeks if allowed to discharge without recharging.

In a vehicle dealership environment, there are typically many vehicles, frequently in the 100's, which are waiting to be sold. These vehicles are generally not driven every day, and are not being regularly recharged through normal driving. Over time, electrical loads from the vehicle, which continue after the vehicle is shut off, and the self-discharge of the battery combine to discharge the battery. A lead acid battery will begin to degrade and decay if allowed to remain discharged. This discharge may result in a failed battery on the dealer lot, or a battery which fails shortly after being sold to a customer. Both situations cost time, aggravation, and significant money for the original equipment manufacturer (OEM), vehicle dealership, and vehicle owner/customer.

Starting a vehicle begins the process of recharging the vehicle's battery. The vehicle alternator, powered by the running engine, charges the battery through the regulation system, and restores the battery charge over time.

The costs and effort to identify, locate, and periodically charge a vehicle's battery can be inconvenient and costly for a dealership, and selection of a vehicle for starting/charging often involves guesswork, and occasionally is necessary due to the presence of a completely discharged (dead) battery.

It would accordingly be beneficial to provide a system and method for automatically determining the vehicles in a dealership environment requiring a battery charge, automatically starting the engine of the identified vehicles to initiate the recharging of the corresponding batteries thereof, monitoring the recharging of such batteries to ensure a safe and adequate charging of the corresponding batteries, and discontinuing the recharging process upon the completion of a predetermined condition, such as the corresponding batteries reaching a desirable charge level.

### SUMMARY OF THE INVENTION

The concept of the invention is to remotely determine a battery's health, determine if the vehicle is in a safe location and state to commence a remote start of the vehicle, to start the vehicle remotely, and determine how long/how frequently the engine should be running to maintain proper charge levels. Typically, this process can be completed in a matter of minutes.

According to an embodiment of the present invention, vehicle battery charging system includes a vehicle having an internal combustion engine, a battery charged by operation of the internal combustion engine, and a telematics system. The telematics system includes a controller, a wireless communication transceiver in signal communication with the controller, and at least one monitoring device in signal communication with the controller, the at least one monitoring device including a battery monitor for determining a state of charge of the battery. A remote computing device is in signal communication with the wireless communication transceiver via a network. The remote computing device is configured to execute an algorithm including at least one condition that must be met to determine that a charging session with respect to the battery of the vehicle is be conducted with the at least one condition including the state of charge of the battery being below a lower threshold value. The remote computing device sends a signal to the controller to operate the internal combustion engine and charge the battery when each of the at least one conditions of the algorithm are determined to be met by the remote computing device.

A method of automatically charging a battery of a vehicle is also disclosed and includes the steps of monitoring a state of charge of the battery by a battery monitor of the vehicle; communicating the state of charge of the battery to a remote computing device via a wireless communication transceiver of the vehicle; determining, by the remote computing device, to conduct a charging session with respect to the battery when the state of charge of the battery is below a lower threshold value; and sending a signal originating from the remote computing device to the wireless communication transceiver of the vehicle to operate an internal combustion engine of the vehicle for charging the battery.

### BRIEF DESCRIPTION OF THE DRAWINGS

The above, as well as other advantages of the present invention, will become readily apparent to those skilled in the art from the following detailed description of a preferred embodiment when considered in the light of the accompanying drawings.

FIG. 1 is a schematic block diagram showing a vehicle battery remote charging and maintenance system according to an embodiment of the present invention; and

FIG. 2 is a schematic diagram showing an exemplary worksite (vehicle dealership) utilizing the vehicle battery remote charging and maintenance system of FIG. 1.

### DETAILED DESCRIPTION OF EXEMPLARY EMBODIMENTS OF THE INVENTION

The following detailed description and appended drawings describe and illustrate various exemplary embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical, unless specified otherwise. The exemplary embodiments are provided so that this disclosure will be both thorough and complete, and will fully convey the scope of the invention and enable one of ordinary skill in the art to make, use, and practice the invention.

The terms “coupled,” “fixed,” “attached to,” “communicatively coupled to,” “operatively coupled to,” and the like refer to both (i) direct connecting, coupling, fixing, attaching, communicatively coupling; and (ii) indirect connecting coupling, fixing, attaching, communicatively coupling via one or more intermediate components or features, unless otherwise specified herein. “Communicatively coupled to” and “operatively coupled to” can refer to physically and/or electrically related components, depending on the circumstances.

Embodiments of the present invention described herein, with reference to flowchart illustrations and/or block diagrams of methods or apparatuses (the term “apparatus” includes systems and computer program products), will be understood such that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a particular machine, such that the instructions, which execute via the processor of the computer or other programmable data processing apparatus, create mechanisms for implementing the functions/acts specified in the flowchart and/or block diagram block or blocks.

These computer program instructions may also be stored in a computer-readable memory that can direct a computer or other programmable data processing apparatus to function in a particular manner, such that the instructions stored in the computer readable memory produce an article of manufacture including instructions, which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions, which execute on the computer or other programmable apparatus, provide steps for implementing the functions/acts specified in the flowchart and/or block diagram block or blocks. Alternatively, computer program implemented steps or acts may be, depending on the circumstances, combined with operator or human implemented steps or acts in order to carry out an embodiment of the invention, unless specified otherwise herein.

While certain exemplary embodiments have been described and shown in the accompanying drawings, it is to be understood that such embodiments are merely illustrative of, and not restrictive on, the broad invention, and that this invention not be limited to the specific constructions and arrangements shown and described, since various other changes, combinations, omissions, modifications and/or substitutions, in addition to those set forth in the above paragraphs, are possible. Those skilled in the art will appreciate that various adaptations, modifications, and/or combinations of the herein described embodiments can be configured without departing from the scope and spirit of the invention. Therefore, it is to be understood that, within the scope of the included claims, the invention may be practiced other than as specifically described herein while still implementing the remaining inventive features of the present system and method.

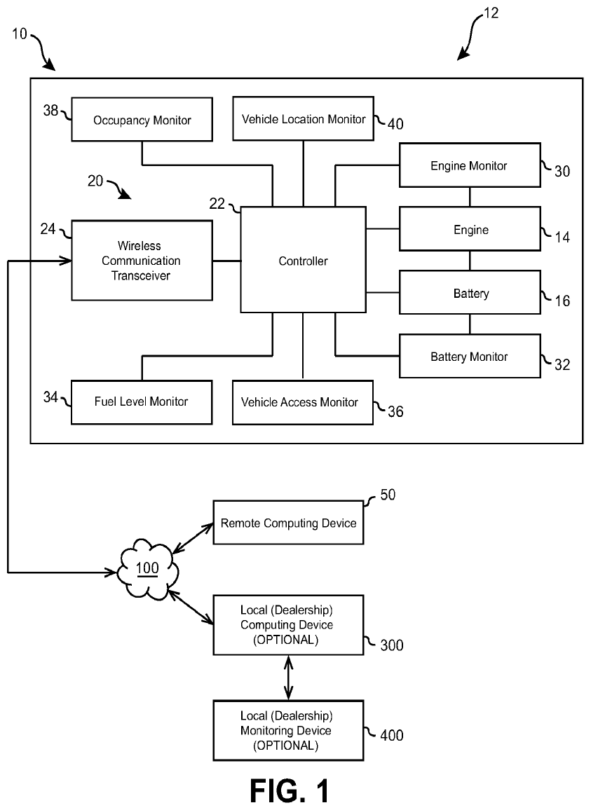

With reference to FIG. 1, the present disclosure relates to an automobile battery remote charging and maintenance system 10, which, for brevity, may be referred to as the charging system 10 hereinafter. As described in the background of the present invention, the charging system 10 may generally be utilized with respect to a vehicle 12 having an internal combustion engine 14 and a battery 16. The internal combustion engine 14 converts the chemical energy stored within a fuel (not shown, such as gasoline or diesel fuel) into kinetic energy utilized in moving a component (such as a piston) of the internal combustion engine 14. This kinetic energy may in turn be utilized in charging the battery 16 of the vehicle 12, such as by use of an alternator (not shown) of the corresponding vehicle 12. Additionally, the energy stored within the battery 16 may be utilized in starting the movement of the internal combustion engine 14 prior to the initiation of the combustion of the corresponding fuel. The battery 16 must accordingly have at least a minimal degree of charge to start the corresponding internal combustion engine 14, which depletes some of the energy stored to the battery 16, and subsequent operation of the internal combustion engine 14 may then be utilized in recharging the battery 16 as a result of the mechanical movement occurring therein. Although the vehicle 12 is generally described with reference to an automobile hereinafter, it should be readily understood that any alternative vehicle or system utilizing the relationships described herein may be adapted for use with the charging system 10 of the present disclosure, as desired.

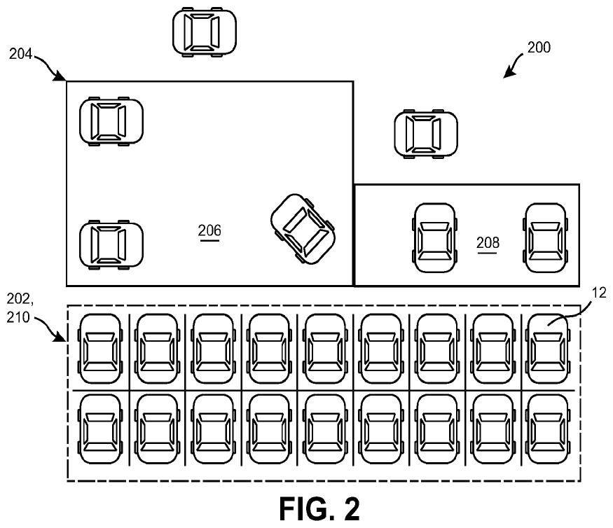

With reference to FIG. 2, the vehicle 12 may be associated with a geographic location or worksite 200 at which the vehicle 12 is stored or otherwise positioned during operation of the disclosed charging system 10. As one non-limiting example, the location or worksite 200 may refer to an vehicle (car) dealership 200 wherein one or more vehicles 12 having the characteristics described herein is/are stored, although the charging system 10 may be utilized in conjunction with substantially any form of location or worksite 200 utilizing outdoor storage of motor vehicles or the like.

The vehicle dealership 200 may typically include the vehicle(s) 12 being stored in an outdoor environment 202, such as a dealership parking lot 202, where the vehicles 12 are exposed to the ambient environment. Those vehicles 12 stored in the parking lot 202 are accordingly able to safely and readily expel any exhaust gases generated by the operation of the internal combustion engine 14 to the ambient environment in a manner not causing harm to any person in proximity to the operating vehicles 12. In contrast, one or more of the vehicles 12 may be, in some circumstances, stored or otherwise positioned within an indoor environment 204 associated with the vehicle dealership 200. In the present example, the vehicle dealership 202 includes an indoor display area 206 and an indoor garage or maintenance area 208 forming the indoor environment 204, each of which may not be suitable for operation of the internal combustion engine 14 and expulsion of the corresponding exhaust gases for an extended period of time due to the potential for harm to any person within the display facility 206 and/or the garage 208.

The charging system 10 as described herein is configured for use only with those vehicles 12 having a telematics system 20 incorporated therein that meets certain requirements in monitoring the instantaneous status of each of the corresponding vehicles 12 and in communicating signals to and from each of the corresponding vehicles 12 with respect to an externally provided remote computing device 50. Referring back to FIG. 1, the charging system 10 is described with reference to an exemplary vehicle 12 having a suitable telematics system 20 incorporated therein that communicates signals to or from an exemplary remote computing device 50 via an intervening network 100. The telematics system 20 utilized in the vehicle 12 may be OEM installed or may be retrofitted as an aftermarket accessory to the vehicle 12, so long as the corresponding telematics system 20 meets the minimum requirements in ascertaining the status of the vehicle 12 and communicating with the remote computing device 50 in the manner described hereinafter.

The network 100 provides wireless communications among the components of the charging system 10 and the environment thereof, including other devices local or remote to those illustrated, such as additional mobile devices, servers, and other devices communicatively coupled to network 100, including those not illustrated in FIG. 1. The network 100 is singularly depicted for illustrative convenience in FIG. 1, but may include more than one network without departing from the scope of these descriptions. In some embodiments, the network 100 may provide one or more cloud-based services or operations. The network 100 may be or include an enterprise or secured network, or may be implemented, at least in part, through one or more connections to the Internet. The network may, for example, utilize what may be referred to as a cellular based Internet of Things (IOT) network for performing cloud-based communications between the vehicle 12 and the remote computing device 50, among other potential devices and components as described hereinafter.

The telematics system 20 of the vehicle 12 generally includes a controller 22 and a wireless communication transceiver 24. The controller 22 may refer to any computing device having the necessary processor, memory, and stored or programmed instructions for carrying out the processes described herein. The controller 22 is configured to send and/or receive signals relating to the status of all and any components shown as being in signal communication therewith via the use of lines extending between the various components as shown in FIG. 1. The controller 22 is capable of sending and receiving data and is also capable of initiating certain actions with respect to those components in signal communication with the controller 22. The controller 22 is shown as a single controller in communication with the transceiver 24 and each of the corresponding components of the vehicle 12 associated with the telematics system 20, but it should be understood that the controller 22 may represent a plurality of interconnected computing devices capable of communicating and interpreting the signals in the manner described herein without departing from the scope of the present invention.

The wireless communication transceiver 24 may be any wireless communication device capable of wirelessly communicating with the remote computing device 50 via the network 100. As mentioned previously, the wireless communication transceiver 24 may preferably be a cellular transceiver capable of communicating with the remote computing device 50 via the network 100 via traditional cellular communication methods and protocols. The use of the cellular transceiver may be preferable due to the long range capabilities of such a transceiver in maintaining a connection to the network 100. However, alternative forms of wireless transceivers may be utilized without departing from the scope of the present invention, such as a WiFi transceiver, a Bluetooth transceiver, or a radio frequency transceiver, as non-limiting examples. In some embodiments, such an alternative form of transceiver may communicate with another wireless communication device (not shown) associated with the geographic location or worksite 200 that in turn communicates data to the remote computing device 50 via the network 100. For example, if the wireless communication transceiver 24 utilizes WiFi, wireless signals may be sent and/or received between the wireless communication transceiver 24 and a wireless router and connected modem (not shown) associated with a corresponding vehicle dealership 200, which in turn communicates with the remote computing device 50 via the network 100 using basic internet methodology. It should be readily apparent that substantially any series of operatively interconnected devices facilitating wireless signal transfer between the wireless communication transceiver 24 and the remote computing device 50 may be utilized in carrying out the novel features of the present invention, as desired, and hence the operative connections shown and described herein are not necessarily limiting to the present invention.

The vehicle 12 must include certain monitoring components for monitoring or sensing certain aspects of the vehicle 12 for carrying out the method of the present invention in a safe and effective manner. Preferably, the vehicle 12 includes each of the components described hereinafter, but it should be understood that any sub-combination of the sensed states or conditions of the vehicle 12 and components thereof may be utilized in carrying out the basic concepts of the disclosed method, although certain sub-combinations may present concerns of effectiveness or safety, depending on the instantaneous circumstances. The components described hereinafter are generally referred to as monitors of certain states or conditions of the vehicle 12 and components thereof, which may refer to any sensors, probes, or the like associates with measuring or determining the described states or conditions.

The vehicle 12 includes an engine monitor 30 in signal communication with the controller 22. The engine monitor 30 is configured to determine whether or not the internal combustion engine 14 of the vehicle 12 is currently operating, thereby establishing whether the engine 14 has already been ignited or is in need of ignition to begin a process of recharging the battery 16.

A battery monitor 32 of the vehicle 12 is in signal communication with the controller 22 and is configured to monitor characteristics of the battery 16. Specifically, the battery monitor 32 determines a state of charge (SOC) of the battery 16, which may be communicated as a percentage of a maximum charge associated with the battery 16.

The vehicle 12 also includes a fuel level monitor 34 in signal communication with the controller 22, wherein the fuel level monitor 34 is configured to monitor an instantaneous fuel level of the vehicle 12. The fuel level may be determined as a percentage of the maximum fuel that the vehicle 12 can hold or as a quantity of the fuel contained within a fuel tank of the vehicle 12, such as determining the number of gallons of fuel contained therein.

The vehicle 12 further includes one or more vehicle access monitors 36 with each of the vehicle access monitors 36 in respective signal communication with the controller 22. Each of the vehicle access monitors 36 is associated with an access point into an interior of the vehicle or into a compartment of the vehicle. For example, the vehicle 12 may include a plurality of the access monitors 36 and may include a respective access monitor 36 associated with each of the doors of the vehicle 12 leading to the passenger compartment thereof, an access monitor 36 associated with each of the trunks or storage compartments of the vehicle 12, and/or an access monitor 36 associated with the hood of the vehicle 12 providing access to the internal components of the vehicle 12, such as the internal combustion engine 14 and the battery 16. Each of the access monitors 36 may be a sensor or the like configured to determine an open or closed state or condition of the corresponding door, trunk, or hood.

The vehicle 12 additionally includes one or more occupancy monitors 38 with each of the occupancy monitors 38 in respective signal communication with the controller 22. Each of the occupancy monitors 38 is configured to determine whether any passengers (including a driver of the vehicle 12) are present within the passenger compartment of the vehicle 12. The vehicle 12 may include a plurality of the occupancy monitors 38 with each of the occupancy monitors 38 associated with detecting the presence of a person in a specific seat or area of the passenger compartment, or even other areas of the vehicle 12 that may house a person, such as the trunk area of the vehicle 12. The occupancy monitor 38 may take one or any of a number of different forms, and may in some circumstances include multiple different forms utilized in combination for ascertaining the occupancy of each seat and/or area. Examples of possible occupancy monitors 38 include a load or pressure sensor for determining whether a person is applying a force to a seat or other feature of the passenger compartment, a radio frequency (RF) sensor for determining whether a key of the driver is present within the passenger compartment, various cameras or other sensors associated with imagining the interior of the vehicle 12, which may include an infrared (IR) camera sensor, an ultrasonic sensor, or a more traditional visual camera sensor, or the use of door switches that imply the presence or lack of presence of any occupants.

Finally, the vehicle 12 may include a vehicle location monitor 40 in signal communication with the controller 22. The vehicle location monitor 40 is configured to determine a geographic location of the vehicle 12, which may include determining whether the vehicle 12 is located within a predetermined area 210 of the geographic location or worksite 200 associated with the charging system 10, which is indicated by the area bounded by the dashed lines within FIG. 2. Preferably, the vehicle location monitor 40 is a global positioning system (GPS) based device that can accurately (within acceptable error) determine the geographic position of the vehicle 12, which may include providing the instantaneous coordinates (longitude and latitude) of the vehicle 12.

The predetermined area 210 may refer to one or more areas where the internal combustion engine 14 of the vehicle 12 can be safely operated to avoid concerns relating to the exhausting of gases, which generally limits the predetermined area 210 to outdoor locations or indoor locations having adequate ventilation. The predetermined area 210 may also be determined based on the proximity thereof to the worksite 200 or the accessibility of the predetermined area 210 to agents associated with the worksite 200, such as limiting the predetermined area 210 to only those positions within a vehicle dealership 200 that are accessible to salespersons, mechanics, or other personnel associated with the vehicle dealership 200. The predetermined area 210 may also be divided into multiple sub-areas, such as multiple different parking lots located on the worksite 200. In the present example, the parking lot 202 is contained within the predetermined area 210 while the indoor display area 206, the indoor garage or maintenance area 208, and all other areas of the vehicle dealership 200 external to the predetermined area 210 are omitted from the predetermined area 210, as would be all areas external to the vehicle dealership 200 itself. The method according to the present invention may relate to geofencing the predetermined area 210 via the use of the GPS coordinates of the vehicle 12 as determined by the vehicle location monitor 40.

In the present embodiment, the remote computing device 50 may include the storage of data associated with the coordinates that correspond to the vehicle 12 being within the predetermined area 210 such that a determination can be made regarding the vehicle 12 being within the predetermined area 210 via access to the GPS coordinates of the vehicle 12, as communicated by the wireless communication transceiver 24 to the network 100. It should be understood that the remote computing device 50 may also include the ability to store the coordinates of a plurality of different predetermined areas 210 associated with multiple different worksites 200, such as storing the coordinates associated with each of a plurality of different vehicle dealerships 200 utilizing the charging system 10. That is, the vehicle 12 may be determined to be within the predetermined area 210 of any participating vehicle dealership 200 upon a transfer of the vehicle 12 from one dealership to another. In this way, the determination of whether or not the internal combustion engine 14 can be safely operated can be made regardless of the transport of the vehicle 12 between different participating vehicle dealerships 200. However, in some circumstances, the controller 22 may instead include the storage of the coordinates corresponding to locations within the predetermined area 210 of each participating vehicle dealership 200, as opposed to storing this information remotely. In such circumstances, the controller 22 may determine whether the vehicle is within a qualifying predetermined area 210 and may communicate this data to the remote computing device 50 absent the need for further analysis or determinations thereat.

FIG. 1 further discloses the presence of a local computing device 300 that may be housed at or otherwise associated with the worksite 200, such as the exemplary vehicle dealership 200. The presence or use of the local computing device 300 as a part of the charging system 10 may be optional, depending on the configuration of the charging system 10 and the programming of the controller 22 and/or the remote computing device 50. The local computing device 300 is in signal communication with the remote computing device 50 via the network 100, and may be utilized by the remote computing device 50 in determining whether the worksite 200 is instantaneously capable of safely initiating and conducting the recharging of the battery 16 of a vehicle 12 located within the predetermined area 210. For example, the remote computing device 50 may be configured to only allow the recharging process to occur when the corresponding worksite 200 is adequately staffed or otherwise open for operation, thereby eliminating situations wherein a vehicle 12 is undesirably started and operated in the absence of human supervision or access.

In the example of the vehicle dealership 200, an agent of the dealership 200 may toggle the availability of the charging system 10 and associated method on or off via the local computing device 300 depending on the presence of employees at the dealership 200 or the availability of the dealership 200 to the general public, as non-limiting examples. As another example, the local computing device 300 may be utilized to communicate with the remote computing device 50 which predetermined time periods should be associated with operation of the charging system 10 and ignition of any internal combustion engines 14 thereat, thereby eliminating the need for active toggling between the on/off settings. Such a method may include the programming of the remote computing device 50 via the local computing device 300. As another example, the local computing device 300 may be programmed to communicate the on/off setting to the remote computing device 50 each time a suitable time period is reached or ended. In the absence of the local computing device 300, the remote computing device 50 may be preprogrammed to know the appropriate time periods to utilize the charging system 10, thereby eliminating the intervention of the local computing device 300.

FIG. 1 also depicts the optional presence of a local monitoring device 400 in signal communication with the local computing device 300, which is in turn in communication with the remote computing device 50 via the network 100. The local monitoring device 400 may be utilized in certain circumstances where the GPS based vehicle location monitor 40 is not relied upon by the charging system 10 in determining whether the associated vehicle 12 is within the predetermined area 210. The local monitoring device 400 may be any device configured to determine the position of the vehicle 12 relative to the corresponding worksite 200. For example, a camera based system may be utilized to identify the vehicle 12 and determine the presence thereof within the predetermined area 210. As another example, the local monitoring device 400 may utilize wireless communication methods to triangulate the position of the vehicle 12 via the sending of signals between the wireless communication transceiver 24 and two or more wireless communication transceivers located at the worksite 200. The local monitoring device 400 may also be configured to determine the instantaneous status of the worksite 200 regarding the availability of staff (among other listed factors) and the permissibility of the use of the charging system 10 within specific time periods.

The remote computing device 50 includes a processor, memory, and appropriate instructions for carrying out the processes described herein for utilizing the charging system 10 as shown and described. The remote computing device 50 is also operatively coupled to the network 100 to allow for communication between the wireless communication transceiver 24 and the remote computing device 50 in the manner described, and may accordingly include any necessary communication devices such as a suitable transceiver. The remote computing device 50 may be considered to be a cloud-based service provider, and may alternatively be referred to as a remote server of the charging system 10. As mentioned earlier, the remote computing device 50 may store, depending on the circumstances, data associated with the positions corresponding to the predetermined area 210 and/or data associated with appropriate time periods that correspond to the worksite 200 being in a state or condition for performing an automatic charging process via the charging system 10 to eliminate the need for intervention via the optionally utilized local computing device 300 and/or the local monitoring device 400.

In all circumstances, the remote computing device 50 includes instructions stored thereto that relate to a vehicle charging algorithm utilized in determining whether a set of conditions or circumstances are present that indicate the need to initiate a charging session with respect to the vehicle 12, to then monitor the charging process to determine whether the charging process has adequately recharged the battery 16 of the vehicle 12, and to potentially cease the charging process when it is determined that the charging process has been completed or that the state or condition of the vehicle 12 has changed to necessitate the completion of the charging process. The determinations associated with the vehicle charging algorithm are elaborated on hereinafter when describing a method of use of the disclosed charging system 10.

The remote computing device 50 is in signal communication with the vehicle 12 regardless of the operation of the internal combustion engine 14. That is, communications may take place between the telematics system 20 of the vehicle 12 and the remote computing device 50 whenever the battery 16 of the vehicle 12 is capable of providing the necessary energy for powering the described components of the telematics system 20 during periods when the internal combustion engine 14 is not in use. The charging process may be initiated via a communication from the telematics system 20 to the remote computing device 50 or via a communication from the remote computing device 50 to the telematics system 20.

For example, in some embodiments the telematics system 20 may continuously or periodically communicate certain data to the remote computing device 50 to allow the remote computing device 50 to determine whether additional states or conditions of the vehicle 12 must be ascertained and analyzed according to the vehicle charging algorithm. Specifically, the SOC of the battery 16 may be periodically communicated to the remote computing device 50 and the remote computing device 50 may make the additional determinations according to the vehicle recharging algorithm whenever the SOC is determined to be below a lower threshold value known by (stored to the memory of) the remote computing device 50, such as being below a predetermined percentage of maximum charge level. In other circumstances, the controller 22 may monitor the SOC of the battery 16 and may only initiate a communication with the remote computing device 50 when a determination is made by the controller 22 that the SOC is below a predetermined lower threshold value known by the controller 22.

As another example, the remote computing device 50 may continuously or periodically send a communication to the telematics system 20 of the vehicle for interrogating the telematics system 20 regarding the SOC of the battery 16. The telematics system 20 then sends a signal communicating the SOC of the battery 16 to the remote computing device 50, and the remote computing device 50 once again determines whether the SOC is below a predetermined lower threshold value indicating the need to evaluate additional states or conditions of the vehicle 12 to determine whether a charging session can be properly and safely initiated.

The periodic communications described above with respect to either method of initiating the charging session may occur monthly, daily, hourly, or at pre-specified times throughout the day, as non-limiting examples. In some embodiments, the communications regarding the SOC of the battery 16 may only occur within those time frames already known by the controller 22 and/or the remote computing device 50 where the corresponding worksite 200 is deemed to be in a state or condition for performing the charging session, such as being staffed, secure, open/closed to the public, etc. The limiting of such communications to these time frames may eliminate one of the determinations made by the vehicle charging algorithm as described hereinafter.

Upon receipt of data indicating that the SOC of the battery 16 is below the lower threshold value, the remote computing device 50 performs the additional determinations associated with data originating from the telematics system 20, and more specifically each of the identified monitors 30, 32, 34, 36, 40 of the vehicle 12. As mentioned above, it should be understood that the present invention is not necessarily limited to the described set of circumstances corresponding to the initiation of the charging session, and may include only sub-combinations of the described determinations, or even additional determinations not contemplated herein, as necessary. However, the algorithm as described hereinafter ensures that the charging session can be accomplished safely and securely, and thus may represent a preferable set of circumstances.

As one condition of the algorithm, the remote computing device 50 determines whether the internal combustion engine 14 is already in operation via a signal from the engine monitor 30, and thus does not require the use of the charging system 10 to begin the recharging of the battery 16.

Another condition of the algorithm corresponds to the remote computing device 50 determining whether the fuel level of the vehicle, as determined by the fuel level monitor 34, is above a lower threshold value. The lower threshold value of the fuel level may be based on a percentage of fuel capable of being stored in the fuel tank or a set quantity of the fuel (gallons) stored therein. This determination is necessary to ensure that the conducting of the charging session does not deplete the fuel of the vehicle 12 in manner restricting subsequent use of the vehicle 12.

Yet another condition of the algorithm corresponds to the remote computing device 50 determining whether any of the corresponding vehicle access monitors 36 indicates that a door, trunk, hood, or similar structure of the vehicle 12 is currently in an open state, as opposed to being in a closed state.

The remote computing device 50 further determines, as a condition of the algorithm, whether any of the associated occupancy monitors 38 indicates the presence or non-presence of a person within the passenger compartment of the vehicle 12.

Lastly, another condition of the algorithm corresponds to the remote computing device 50 determining whether the vehicle 12 is currently located within a predetermined area 210 of the worksite 200 corresponding to the ability to securely and safely carry out the charging session, as indicated by the coordinates originating from the vehicle location monitor 40.

The algorithm may determine that a charging session should be initiated when all or a certain subset of the following conditions is met: (1) the SOC is below the lower threshold value; (2) the internal combustion engine 14 is not currently in operation; (3) the fuel level of the vehicle 12 is above the lower threshold value; (4) all vehicle access structures (doors, trunks, or hoods) are in a closed state for preventing access to designated compartments of the vehicle 12; (5) no occupants are determined to be within the passenger compartment of the vehicle 12; (6) the vehicle is positioned within the predetermined area 210 corresponding to safe operation of the internal combustion engine 14 and access by staff of the worksite 200; and (7) that the worksite 200, such as the exemplary vehicle dealership 200, is in a state or condition for performing the charging session such that the vehicle may be accessed by the staff of the worksite 200 during such a charging session.

Once the remote computing device 50 determines that all corresponding conditions have been met, the remote computing device 50 sends a signal to the telematics system 20, and more specifically the controller 22, indicating that a remote ignition of the internal combustion engine 14 is to be performed to begin recharging the battery 16. In some circumstances, the internal combustion engine 14 may be allowed to continue operation for a set period of time indicative of adequately recharging the battery 16, such as ten minutes. The remote computing device 50 may also monitor the SOC of the battery 16, via the battery monitor 32, during the charging session to determine whether the SOC has reached an upper threshold value indicative of the completion of the charging session. The remote computing device 50 may accordingly utilize a closed-loop control method where the remote computing device 50 ceases the operation of the internal combustion engine 14 via a signal sent to the telematics system 20 whenever this upper threshold value of SOC is reached, thereby ending the charging session. The discontinuing of the operation of the internal combustion engine 14 may occur prior to the completion of any predetermined time period established for otherwise ceasing the operation thereof, which may also be achieved by the remote computing device 50 sending a signal to the telematics system 20 indicating that the internal combustion engine 14 is to be shut off.

The remote computing device 50 may also monitor any of the other conditions mentioned herein for determining whether to cease operation of the internal combustion engine 14 prior to the reaching of the upper threshold value of SOC or the completion of the set time period of operation. The remote computing device 50 may cease the operation whenever any of the previously described conditions are no longer present, such as fuel level dropping below the lower threshold value of fuel, one of the vehicle access structures being opened, an occupant entering the vehicle 12, the vehicle 12 being moved outside of the predetermined area 210, or an indication that the worksite 200 is no longer suitable for continuing the charging session.

In some circumstances, the maximum time period that the internal combustion engine 14 is to be operated may end without the battery 16 being sufficiently recharged. When such a circumstance occurs, the charging system 10 may initiate another charging session after completion of the initial charging session, and may continue to initiate such charging sessions until the SOC of the battery 16 reaches the upper threshold value. However, the remote computing device 50 may be programmed to limit the number of charging sessions that occur consecutively or periodically (such as daily or monthly), and may further limit the total number of charging sessions that a corresponding vehicle 12 undergoes during the lifetime of the vehicle 12 or the presence of the vehicle 12 at the specified worksite 200.

The charging system 10 and method disclosed herein accordingly provides the benefit of automatically ascertaining the charge level of the battery 16 of an on-site vehicle 12 without the need of the staff of the worksite 200 physically accessing the vehicle 12 and checking the SOC. It also allows for the automatic initiation of the charging session such that human intervention is not required. The use of the present system and method accordingly avoids circumstances where the battery 16 of a vehicle 12 for sale is undesirably depleted (or dead) when being stored at a vehicle dealership 200, which avoids circumstances where a buyer of the vehicle 12 is unsatisfied with the vehicle 12 due to poor battery performance or the need for replacement shortly after acquiring the corresponding vehicle 12. The conditions utilized by the remote computing device 50 in determining when and how to initiate and continue operation of a charging session also ensures that such charging sessions can be carried out safely and effectively within a secure, outdoor environment.

From the foregoing description, one ordinarily skilled in the art can easily ascertain the essential characteristics of this invention and, without departing from the spirit and scope thereof, can make various changes and modifications to the invention to adapt it to various usages and conditions.

I claim:

1. A vehicle battery charging system comprising:
a vehicle having an internal combustion engine, a battery charged by operation of the internal combustion engine, and a telematics system, the telematics system comprising:
a controller;
a wireless communication transceiver in signal communication with the controller; and
at least one monitoring device in signal communication with the controller, the at least one monitoring device including a battery monitor for determining a state of charge of the battery; and
a remote computing device in signal communication with the wireless communication transceiver via a network, the remote computing device configured to execute an algorithm including at least one condition that must be met to determine that a charging session with respect to the battery of the vehicle is be conducted, the at least one condition including the state of charge of the battery being below a lower threshold value;
wherein the remote computing device sends a signal to the controller to operate the internal combustion engine and charge the battery when each of the at least one conditions of the algorithm are determined to be met by the remote computing device.

2. The vehicle battery charging system of claim 1, wherein the wireless communication transceiver is a cellular transceiver and the network utilizes the Internet.

3. The vehicle battery charging system of claim 1, wherein the at least one condition includes a plurality of the conditions that must be met to determine that a charging session with respect to the battery of the vehicle is be conducted, wherein the plurality of the conditions further includes the vehicle being located within a predetermined area known by or communicated to the remote computing device.

4. The vehicle battery charging system of claim 3, wherein the at least one monitoring device includes a plurality of the monitoring devices, wherein the plurality of the monitoring devices further includes a vehicle location monitor configured to determine a geographic position of the vehicle.

5. The vehicle battery charging system of claim 4, wherein the vehicle location monitor utilizes GPS coordinates to determine whether the vehicle is within the predetermined area.

6. The vehicle battery charging system of claim 3, wherein the predetermined area is an outdoor area of a vehicle dealership.

7. The vehicle battery charging system of claim 1, wherein the at least one condition includes a plurality of the conditions that must be met to determine that a charging session with respect to the battery of the vehicle is be conducted, wherein the plurality of the conditions further includes a fuel level of the vehicle being above a lower threshold fuel level.

8. The vehicle battery charging system of claim 7, wherein the at least one monitoring device includes a plurality of the monitoring devices, wherein the plurality of the monitoring devices further includes a fuel level monitor configured to determine the fuel level of the vehicle.

9. The vehicle battery charging system of claim 1, wherein the at least one condition includes a plurality of the conditions that must be met to determine that a charging session with respect to the battery of the vehicle is be conducted, wherein the plurality of the conditions further includes a vehicle access structure of the vehicle being in a closed state.

10. The vehicle battery charging system of claim 9, wherein the at least one monitoring device includes a plurality of the monitoring devices, wherein the plurality of the monitoring devices further includes a vehicle access monitor configured to determine an open or closed state of the vehicle access structure.

11. The vehicle battery charging system of claim 9, wherein the vehicle access structure is one of a door, a trunk, or a hood of the vehicle.

12. The vehicle battery charging system of claim 1, wherein the at least one condition includes a plurality of the conditions that must be met to determine that a charging session with respect to the battery of the vehicle is be conducted, wherein the plurality of the conditions further includes a passenger compartment of the vehicle not being occupied by a human occupant.

13. The vehicle battery charging system of claim 12, wherein the at least one monitoring device includes a plurality of the monitoring devices, wherein the plurality of the monitoring devices further includes occupancy monitor configured to determine whether a human occupant is present within the passenger compartment of the vehicle.

14. The vehicle battery charging system of claim 13, wherein the occupancy monitor is one of a visual camera, a load sensor, a pressure sensor, an ultrasonic sensor, an infrared camera, or a door switch.

15. The vehicle battery charging system of claim 1, wherein the at least one condition includes a plurality of the conditions that must be met to determine that a charging session with respect to the battery of the vehicle is be conducted, wherein the plurality of the conditions further includes the charging session occurring within a predetermine time interval corresponding to a worksite at which the vehicle is located being staffed.

16. The vehicle battery charging system of claim 1, wherein the at least one condition includes a plurality of the conditions that must be met to determine that a charging session with respect to the battery of the vehicle is be conducted, wherein the plurality of the conditions further include the vehicle being located within a predetermined area known by or communicated to the remote computing device, a fuel level of the vehicle being above a lower threshold fuel level, a vehicle access structure of the vehicle being in a closed state, a passenger compartment of the vehicle not being occupied by a human occupant, and the charging session occurring within a predetermine time interval corresponding to a worksite at which the vehicle is located being staffed.

17. The vehicle battery charging system of claim 16, wherein the at least one monitoring device includes a plurality of the monitoring devices, wherein the plurality of the monitoring devices further includes a vehicle location monitor configured to determine a geographic position of the vehicle, a fuel level monitor configured to determine a fuel level of the vehicle, a vehicle access monitor configured to determine an open or closed state of the vehicle access structure, and an occupancy monitor configured to determine whether a human occupant is present within the passenger compartment of the vehicle.

18. The vehicle battery charging system of claim 1, wherein the remote computing device is configured to send a signal to the controller of the vehicle to cease the conducting of the charging session by discontinuing operation of the internal combustion engine when the state of charge of the battery is above an upper threshold value.

19. A method of automatically charging a battery of a vehicle comprising:
monitoring a state of charge of the battery by a battery monitor of the vehicle;
communicating the state of charge of the battery to a remote computing device via a wireless communication transceiver of the vehicle;
determining, by the remote computing device, to conduct a charging session with respect to the battery when the state of charge of the battery is below a lower threshold value; and
sending a signal originating from the remote computing device to the wireless communication transceiver of the vehicle to operate an internal combustion engine of the vehicle for charging the battery.

20. The method of claim 19, wherein the remote computing device determines to conduct the charging session with respect to the battery when the following additional conditions are met:
the vehicle is located within a predetermined area known by or communicated to the remote computing device;
a fuel level of the vehicle is above a lower threshold fuel level;
a vehicle access structure of the vehicle is in a closed state;
a passenger compartment of the vehicle is not occupied by a human occupant; and
a worksite at which the vehicle is located is instantaneously staffed.
